(19) United States
(12) Patent Application Publication
(10) Pub. No.: US 2026/0290418 A1
(43) Pub. Date: Sep. 24, 2026

(54) SEMICONDUCTOR DEVICE

(71) Applicant: Kioxia Corporation, Tokyo (JP)

(72) Inventors: Kiyotaro ITAGAKI, Ota (JP); Kazuaki KAWAGUCHI, Kokubunji (JP); Dongxu LI, Kawasaki (JP)

(73) Assignee: Kioxia Corporation, Tokyo (JP)

(21) Appl. No.: 19/309,701

(22) Filed: Aug. 26, 2025

(30) Foreign Application Priority Data
Mar. 21, 2025 (JP) 2025-047341

(51) Int. Cl. G11C 7/22; G11C 7/10

(52) U.S. Cl. CPC G11C 7/222; G11C 7/1057; G11C 2207/2254

(57) ABSTRACT

A semiconductor device includes: an electrode; a pull-up circuit and a pull-down circuit; an internal circuit that outputs the data; a control circuit configured to be able to execute an operation of the internal circuit and a calibration operation to adjust output impedances of the pull-up circuit and the pull-down circuit; and a clock signal generation circuit that supplies a first clock signal to the control circuit in a state where the calibration operation is in execution. When an instruction to execute the calibration operation is input during execution of the operation of the internal circuit, the clock signal generation circuit outputs the first clock signal in a first period during execution of the operation and does not output the first clock signal in a second period during execution of the operation in a time period from the input of the instruction to completion of the calibration operation.

### CROSS-REFERENCE TO RELATED APPLICATIONS

This application is based upon and claims the benefit of Japanese Patent Application No. 2025-047341, filed on Mar. 21, 2025, the entire contents of which are incorporated herein by reference.

### BACKGROUND

### Field

Embodiments described herein relate generally to a semiconductor device.

### Description of the Related Art

There has been known a semiconductor device that includes an electrode, a pull-up circuit and a pull-down circuit configured to control a voltage of the electrode in accordance with input data, and an internal circuit configured to output data to be supplied to the pull-up circuit and the pull-down circuit.

### BRIEF DESCRIPTION OF THE DRAWINGS

FIG. 1 is a schematic block diagram illustrating a configuration of a memory system 10;

FIG. 2 is a schematic side view illustrating an exemplary configuration of the memory system 10;

FIG. 3 is a schematic plan view illustrating the exemplary configuration of the memory system 10;

FIG. 4 is a schematic circuit diagram illustrating a configuration of a part of the memory die MD;

FIG. 5 is a schematic perspective view illustrating a configuration of a part of a memory cell array MCA;

FIG. 6 is a schematic cross-sectional view for describing a read operation;

FIG. 7 is a schematic cross-sectional view for describing a write operation;

FIG. 8 is a schematic cross-sectional view for describing an erase operation;

FIG. 9 is a schematic block diagram illustrating a configuration of a peripheral circuit PC;

FIG. 10 is a schematic circuit diagram illustrating a configuration of a termination resistor adjustment circuit in an input/output control circuit I/O;

FIG. 11 is a table for describing the termination resistor adjustment circuit in the input/output control circuit I/O;

FIG. 12 is a schematic circuit diagram illustrating a configuration of a ZQ circuit;

FIG. 13 is a schematic circuit diagram illustrating the configuration of the ZQ circuit;

FIG. 14 is a timing chart for describing a time period in which a calibration operation is executable;

FIG. 15 is a timing chart for describing a time period in which the calibration operation is executable;

FIG. 16 is a schematic circuit diagram for describing a clock signal generation circuit;

FIG. 17 is a schematic circuit diagram for describing the clock signal generation circuit;

FIG. 18 is a schematic waveform diagram for describing an operation of the clock signal generation circuit; and

FIG. 19 is a timing chart for describing a time period in which the calibration operation is executable in a semiconductor device according to a second embodiment.

### DETAILED DESCRIPTION

A semiconductor device according to one embodiment comprises: an electrode; a pull-up circuit and a pull-down circuit that control a voltage of the electrode in response to input data; an internal circuit that outputs the data supplied to the pull-up circuit and the pull-down circuit; a control circuit configured to be able to execute an operation of the internal circuit and a calibration operation to adjust output impedances of the pull-up circuit and the pull-down circuit; and a clock signal generation circuit that supplies a first clock signal to the control circuit in a state where the calibration operation is in execution. When an instruction to execute the calibration operation is input during execution of the operation of the internal circuit, the clock signal generation circuit outputs the first clock signal in a first period during execution of the operation and does not output the first clock signal in a second period during execution of the operation in a time period from the input of the instruction to completion of the calibration operation.

Next, the semiconductor devices according to embodiments are described in detail with reference to the drawings. The following embodiments are only examples, and not described for the purpose of limiting the present invention.

In this specification, when referring to a “semiconductor device”, it may mean a semiconductor memory device, and may mean a device other than the semiconductor memory device, such as an integrated circuit for computation and an integrated circuit for communication.

In this specification, when referring to a “semiconductor memory device”, it may mean a memory die (memory chip) and may mean a memory system including a controller die, such as a memory card and a Solid State Drive (SSD). Further, it may mean a configuration including a host computer, such as a smartphone, a tablet terminal, and a personal computer. In this specification, as a semiconductor memory device, a NAND flash memory is exemplified. However, the semiconductor memory device may be a memory other than the NAND flash memory.

In this specification, when referring to an “internal circuit”, it may mean a memory cell array and may mean an arithmetic circuit, a communication circuit, and the like.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

### First Embodiment

### Memory System 10

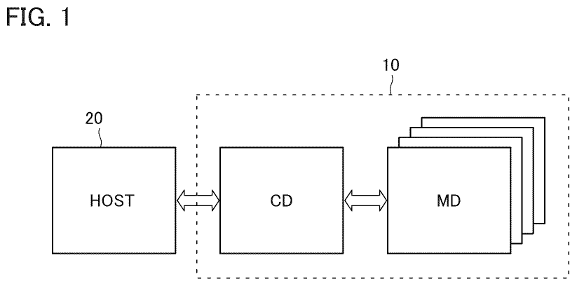

FIG. 1 is a schematic block diagram illustrating a configuration of a memory system 10.

The memory system 10, for example, reads, writes, and erases user data according to a signal transmitted from a host computer 20. The memory system 10 is, for example, a memory card, an SSD, or another system that can store the user data. The memory system 10 includes a plurality of memory dies MD that store the user data and a controller die CD connected to these plurality of memory dies MD and host computer 20. The controller die CD includes, for example, a processor, a RAM, and the like, and performs processing, such as conversion between a logical address and a physical address, bit error detection/correction, a garbage collection (compaction), and a wear leveling.

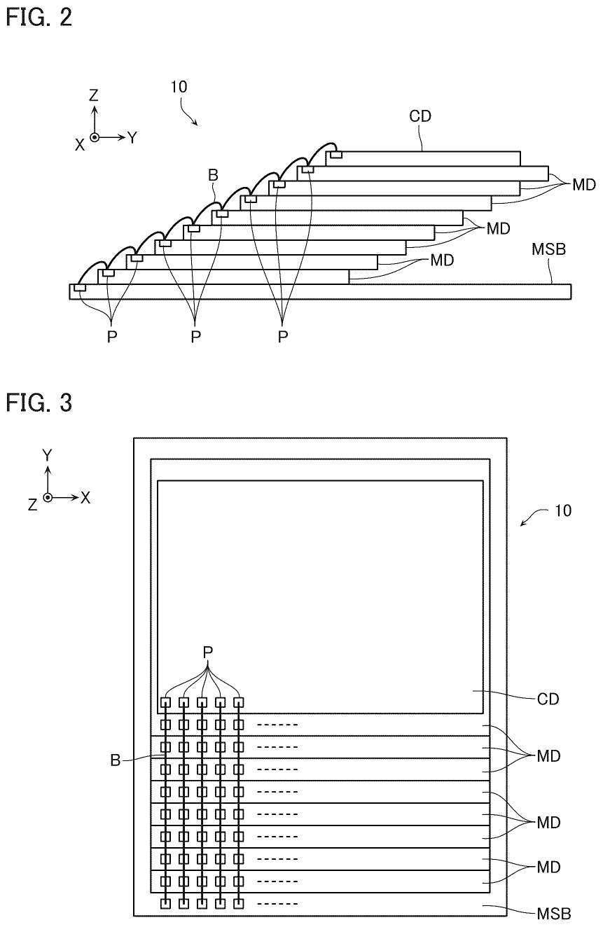

FIG. 2 is a schematic side view illustrating a configuration example of the memory system 10. FIG. 3 is a schematic plan view illustrating the configuration example. For sake of convenience of explanation, FIG. 2 and FIG. 3 omit a part of a configuration.

As illustrated in FIG. 2, the memory system 10 according to the embodiment includes a mounting substrate MSB, the plurality of memory dies MD stacked on the mounting substrate MSB, and the controller die CD stacked on the memory dies MD. On an upper surface of the mounting substrate MSB, pad electrodes P are disposed in a region at an end portion in the Y-direction, and a part of another region is bonded to a lower surface of the memory die MD via an adhesive and the like. On an upper surface of the memory die MD, the pad electrodes P are disposed in a region at an end portion in the Y-direction, and another region is bonded to a lower surface of another memory die MD or the controller die CD via the adhesive and the like. On an upper surface of the controller die CD, the pad electrodes P are disposed in a region at an end portion in the Y-direction.

As illustrated in FIG. 3, the mounting substrate MSB, the plurality of memory dies MD, and the controller die CD each include a plurality of the pad electrodes P arranged in the X-direction. The plurality of pad electrodes P disposed on each of the mounting substrate MSB, the plurality of memory dies MD, and the controller die CD are mutually connected via bonding wires B.

Note that the configuration illustrated in FIG. 2 and FIG. 3 is merely an example, and specific configurations are appropriately adjustable. For example, in the example illustrated in FIG. 2 and FIG. 3, the controller die CD is stacked on the plurality of memory dies MD, and these configurations are connected with the bonding wires B. In such a configuration, the plurality of memory dies MD and the controller die CD are included in one package. However, the controller die CD may be included in a package different from the memory die MD. Additionally, the plurality of memory dies MD and the controller die CD may be connected to one another via through electrodes or the like, not the bonding wires B.

### Configuration of Memory Die MD

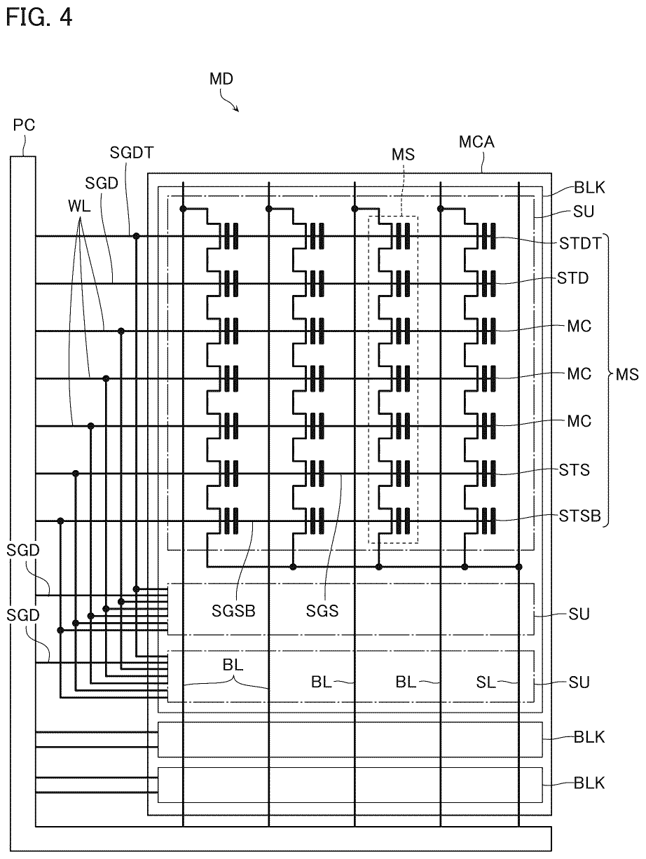

FIG. 4 is a schematic circuit diagram illustrating a configuration of a part of the memory die MD. As illustrated in FIG. 4, the memory die MD includes a memory cell array MCA that stores user data, and a peripheral circuit PC connected to the memory cell array MCA.

### Configuration of Memory Cell Array MCA

The memory cell array MCA includes a plurality of memory blocks BLK. These plurality of memory blocks BLK each include a plurality of string units SU. These plurality of string units SU each include a plurality of memory strings MS. These plurality of memory strings MS have one ends each connected to the peripheral circuit PC via bit lines BL. Furthermore, these plurality of memory strings MS have other ends each connected to the peripheral circuit PC via a common source line SL.

The memory string MS includes drain-side select transistors STDT, STD, a plurality of memory cells MC (memory cell transistors), and a source-side select transistors STS, STSB, which are connected in series between the bit line BL and the source line SL. Hereinafter, the drain-side select transistors STDT, STD and the source-side select transistors STS, STSB may be simply referred to as select transistors STDT, STD, STS, and STSB.

The memory cell MC is a field-effect type transistor including a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores one bit or a plurality of bits of user data. Word lines WL are connected to the respective gate electrodes of the plurality of memory cells MC corresponding to one memory string MS. These word lines WL are disposed corresponding to each memory block BLK, and connected to all of the memory strings MS in the memory block BLK in common.

The select transistors STDT, STD, STS, and STSB are each a field-effect type transistor including a semiconductor layer, a gate insulating film, and a gate electrode. The semiconductor layer functions as a channel region. Select gate lines SGDT, SGD, SGS, and SGSB are connected to the gate electrodes of the select transistors STDT, STD, STS, and STSB, respectively. The drain-side select gate line SGD is disposed corresponding to the string unit SU and connected to all of the memory strings MS in the string unit SU in common. The drain-side select gate line SGDT and the source-side select gate lines SGS, SGSB are disposed corresponding to the memory block BLK, and connected to all of the memory strings MS in the memory block BLK in common.

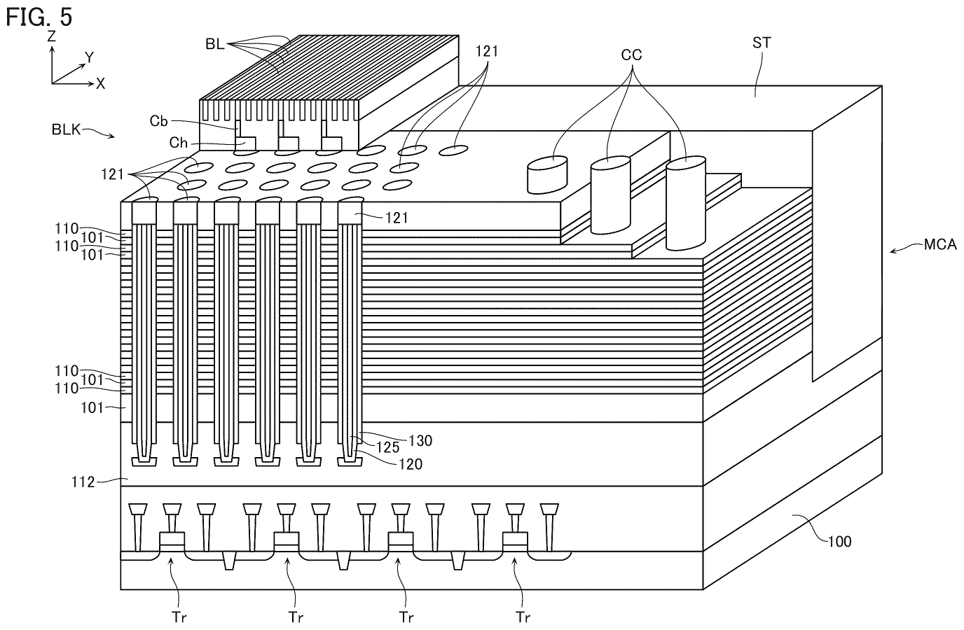

FIG. 5 is a schematic perspective view illustrating a configuration of a part of the memory cell array MCA. The memory cell array MCA is disposed above a semiconductor substrate 100. On an upper surface of the semiconductor substrate 100, a plurality of transistors Tr constituting the peripheral circuit PC are disposed. These plurality of transistors Tr each include a channel region formed of a part of the upper surface of the semiconductor substrate 100, a gate insulating film formed on the upper surface of the semiconductor substrate 100, and a gate electrode faced to the channel region via the gate insulating film.

The memory cell array MCA includes a plurality of memory blocks BLK arranged in the Y-direction. Between two memory blocks BLK adjacent to one another in the Y-direction, an inter-block insulating layer ST of silicon oxide (SiO₂) or the like is disposed. A plurality of bit lines BL arranged in the X-direction and extending in the Y-direction are disposed above the memory cell array MCA.

The memory block BLK includes a plurality of conductive layers 110 arranged in the Z-direction, a plurality of semiconductor columns 120 extending in the Z-direction, and a respective plurality of gate insulating films 130 disposed between the plurality of conductive layers 110 and the plurality of semiconductor columns 120.

The conductive layer 110 is an approximately plate-shaped conductive layer extending in the X-direction. The conductive layer 110 may include a stacked film of a barrier conductive film of titanium nitride (TiN) or the like and a metal film of tungsten (W) or the like, or the like. For example, the conductive layer 110 may contain polycrystalline silicon containing impurities, such as phosphorus (P) or boron (B), or the like. Insulating layers 101 of silicon oxide (SiO₂) or the like are disposed between the plurality of conductive layers 110 arranged in the Z-direction.

Among the plurality of conductive layers 110, one or a plurality of conductive layers 110 positioned at the lowermost layer function as the source-side select gate line SGSB (FIG. 4) and gate electrodes of the plurality of source-side select transistors STSB (FIG. 4) connected to the source-side select gate line SGSB.

One or a plurality of conductive layers 110 positioned above these conductive layers 110 function as the source-side select gate line SGS (FIG. 4) and gate electrodes of the plurality of source-side select transistors STS (FIG. 4) connected to the source-side select gate line SGS.

A plurality of conductive layers 110 positioned above these conductive layers 110 function as the word lines WL (FIG. 4) and gate electrodes of the plurality of memory cells MC (FIG. 4) connected to the word lines WL.

One or a plurality of conductive layers 110 positioned above these conductive layers 110 function as the drain-side select gate line SGD (FIG. 4) and gate electrodes of the plurality of drain-side select transistors STD (FIG. 4) connected to the drain-side select gate line SGD.

One or a plurality of conductive layers 110 positioned above these conductive layers 110 function as the drain-side select gate line SGDT (FIG. 4) and gate electrodes of the plurality of drain-side select transistors STDT (FIG. 4) connected to the drain-side select gate line SGDT.

A semiconductor layer 112 is disposed below the plurality of conductive layers 110. The semiconductor layer 112 may contain, for example, polycrystalline silicon containing N-type impurities such as phosphorus (P), or the like. Between the semiconductor layer 112 and the conductive layer 110, an insulating layer 101 of silicon oxide (SiO₂) or the like is disposed.

The semiconductor layer 112 functions as the source line SL (FIG. 4). The source line SL is disposed in common, for example, for all the memory blocks BLK included in the memory cell array MCA.

The semiconductor columns 120 are arranged in the X-direction and the Y-direction in a predetermined pattern. The semiconductor columns 120 function as the channel regions of the plurality of memory cells MC and the select transistors STDT, STD, STS, and STSB included in one memory string MS (FIG. 4). The semiconductor column 120 is, for example, a semiconductor layer of polycrystalline silicon (Si) or the like. For example, the semiconductor column 120 has an approximately cylindrical shape and includes an insulating layer 125 of silicon oxide or the like in a center part. The semiconductor columns 120 have outer peripheral surfaces each surrounded by the conductive layers 110 and faced to the conductive layers 110.

At an end portion on a bit line BL side of the semiconductor column 120, an impurity region 121 containing N-type impurities, such as phosphorus (P), is disposed. The impurity region 121 is connected to the bit line BL via a contact electrode Ch and a contact electrode Cb.

The gate insulating film 130 has an approximately cylindrical shape that covers the outer peripheral surface of the semiconductor column 120. The gate insulating film 130 includes, for example, a tunnel insulating film, an electric charge accumulating film, and a block insulating film, which are stacked between the semiconductor column 120 and the conductive layers 110. The tunnel insulating film and the block insulating film are, for example, insulating films of silicon oxide (SiO₂) or the like. The electric charge accumulating film is, for example, a film of silicon nitride (SiN) or the like that can accumulate the electric charges. The tunnel insulating film, the electric charge accumulating film, and the block insulating film have approximately cylindrical shapes and extend in the Z-direction along the outer peripheral surface of the semiconductor column 120 excluding a contact portion between the semiconductor column 120 and the semiconductor layer 112.

The gate insulating film 130 may, for example, include a floating gate of polycrystalline silicon including N-type or P-type impurities, or the like.

A plurality of contact electrodes CC are connected to the plurality of conductive layers 110. The plurality of conductive layers 110 are electrically connected to the peripheral circuit PC via these plurality of contact electrodes CC. As illustrated in FIG. 5, these plurality of contact electrodes CC extend in the Z-direction, and have lower ends connected to the conductive layers 110. The contact electrode CC may, for example, include a stacked film of a barrier conductive film of titanium nitride (TiN) or the like and a metal film of tungsten (W) or the like, or the like.

The memory cell array MCA may be formed upside down. For example, the bit line BL may be disposed below the plurality of memory blocks BLK. The semiconductor layer 112 may be disposed above the plurality of conductive layers 110.

### Operation of Memory Cell Array MCA

Next, operations of the memory cell array MCA are described. The memory cell array MCA according to the embodiment is configured to be able to perform a read operation, a write operation, and an erase operation. In the following description, the read operation, the write operation, and the erase operation of the memory cell array MCA may be referred to as a “core operation”.

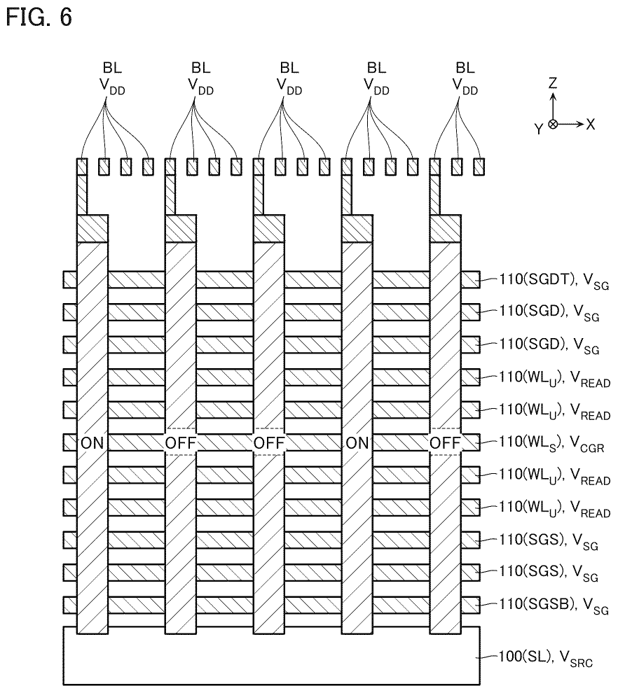

FIG. 6 is a schematic cross-sectional view for describing the read operation. In the following description, a word line WL as a target of the operation is referred to as a selected word line WL_{S}, and the other word lines WL are referred to as unselected word lines WL_{U} in some cases.

In the read operation, for example, an operating voltage V_{DD} is applied to the bit lines BL. A voltage V_{SRC} is applied to the source line SL. The voltage V_{SRC} may be greater than a ground voltage V_{SS}, and may be equal to the ground voltage V_{SS}. The operating voltage V_{DD} is greater than the voltage V_{SRC}.

In the read operation, a voltage V_{SG} is applied to the drain-side select gate lines SGDT, SGD. The voltage V_{SG} is greater than the operating voltage V_{DD}. A voltage difference between the voltage V_{SG} and the operating voltage V_{DD} is greater than threshold voltages of the drain-side select transistors STDT, STD. Therefore, electron channels are formed in the channel regions of the drain-side select transistors STDT, STD, and the operating voltage V_{DD} is transferred to the channel regions.

In the read operation, the voltage V_{SG} is applied to the source-side select gate lines SGS, SGSB. The voltage V_{SG} is greater than the voltage V_{SRC}. A voltage difference between the voltage V_{SG} and the voltage V_{SRC} is greater than threshold voltages of the source-side select transistor STS, STSB. Therefore, electron channels are formed in the channel regions of the source-side select transistors STS, STSB, and the voltage V_{SRC} is transferred to the channel regions.

In the read operation, a read pass voltage V_{READ} is applied to the unselected word lines WL_{U}. The read pass voltage V_{READ} is greater than the operating voltage V_{DD} and the voltage V_{SRC}. Voltage differences between the read pass voltage V_{READ} and the operating voltage V_{DD} and between the read pass voltage V_{READ} and the voltage V_{SRC} are greater than a threshold voltage of the memory cell MC regardless of data stored in the memory cell MC. Therefore, an electron channel is formed in the channel region of an unselected memory cell MC, and the operating voltage V_{DD} and the voltage V_{SRC} are transferred to a selected memory cell MC.

In the read operation, a read voltage V_{CGR} is applied to the selected word line WL_{S}. The read voltage V_{CGR} is smaller than the read pass voltage V_{READ}. A voltage difference between the read voltage V_{CGR} and the voltage V_{SRC} is greater than a threshold voltage of the memory cell MC that stores a part of data. Therefore, the memory cell MC that stores the part of data becomes the ON state. Therefore, a current flows through the bit line BL connected to this memory cell MC. Meanwhile, the voltage difference between the read voltage V_{CGR} and the voltage V_{SRC} is smaller than the threshold voltage of the memory cell MC that stores the part of data. Therefore, the memory cell MC that stores the part of data becomes the OFF state. Therefore, a current does not flow through the bit line BL connected to this memory cell MC.

In the read operation, a sense amplifier SA described later detects the current or the voltage of each bit line BL, latches the detected current or voltage as user data, and outputs the user data to a cache memory CM described later.

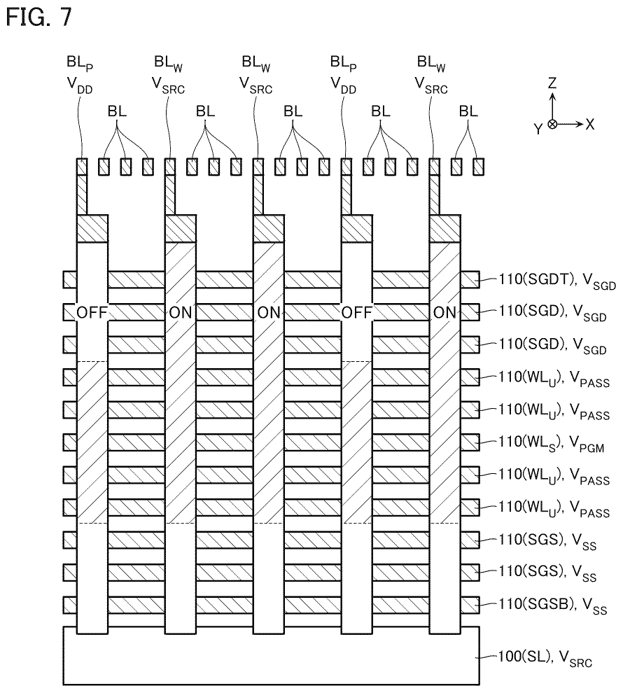

FIG. 7 is a schematic cross-sectional view for describing the write operation.

In the write operation, for example, the voltage V_{SRC} is applied to bit lines BL_{W} connected to the selected memory cells MC on which an adjustment of the threshold voltage is performed among the plurality of selected memory cells MC. The operating voltage V_{DD} is applied to bit lines BL_{P} connected to the selected memory cells MC on which the adjustment of the threshold voltage is not performed among the plurality of selected memory cells MC. Hereinafter, among the plurality of selected memory cells MC, the selected memory cell MC on which the adjustment of the threshold voltage is performed may be referred to as a “write memory cell MC”, and the selected memory cell MC on which the adjustment of the threshold voltage is not performed may be referred to as an “inhibited memory cell MC”.

In the write operation, a voltage V_{SGD} is applied to the drain-side select gate lines SGDT, SGD.

The voltage V_{SGD} is greater than the voltage V_{SRC}. A voltage difference between the voltage V_{SGD} and the voltage V_{SRC} is greater than the threshold voltages of the drain-side select transistors STDT, STD. Therefore, electron channels are formed in the channel regions of the drain-side select transistors STDT, STD connected to the bit lines BL_{W}, and the voltage V_{SRC} is transferred to the channel regions.

Meanwhile, a voltage difference between the voltage V_{SGD} and the operating voltage V_{DD} is smaller than the threshold voltages of the drain-side select transistors STDT, STD. Therefore, the drain-side select transistors STDT, STD connected to the bit lines BL_{P} become the OFF state.

In the write operation, the voltage V_{SRC} is applied to the source line SL, and the ground voltage V_{SS} is applied to the source-side select gate lines SGS, SGSB. Thus, the source-side select transistors STS, STSB become the OFF state.

In the write operation, a write pass voltage V_{PASS} is applied to the unselected word lines WL_{U}. The write pass voltage V_{PASS} is greater than the read pass voltage V_{READ}. A voltage difference between the write pass voltage V_{PASS} and the voltage V_{SRC} is greater than the threshold voltage of the memory cell MC regardless of data stored in the memory cell MC. Therefore, an electron channel is formed in the channel region of the unselected memory cell MC, and the voltage V_{SRC} is transferred to the write memory cell MC.

In the write operation, a program voltage V_{PGM} is applied to the selected word line WL_{S}. The program voltage V_{PGM} is greater than the write pass voltage V_{PASS}.

Here, the voltage V_{SRC} is applied to the channel of the semiconductor column 120 connected to the bit line BL_{W}. A comparatively large electric field is generated between this semiconductor column 120 and the selected word line WL_{S}. Accordingly, the electrons in the channel of the semiconductor column 120 tunnel into the electric charge accumulating film in the gate insulating film 130 (FIG. 5). Accordingly, the threshold voltage of the write memory cell MC increases.

On the other hand, the channel of the semiconductor column 120 connected to the bit line BL_{P} is electrically in a floating state, and the voltage of this channel increases up to around the write pass voltage V_{PASS} by capacitive coupling with the unselected word line WL_{U}. Between this semiconductor column 120 and selected word line WL_{S}, only the electric field smaller than the above-described electric field is generated. Thus, the electrons in the channel of the semiconductor column 120 do not tunnel into the electric charge accumulating film in the gate insulating film 130 (FIG. 5). Therefore, the threshold voltage of the inhibited memory cell MC does not increase.

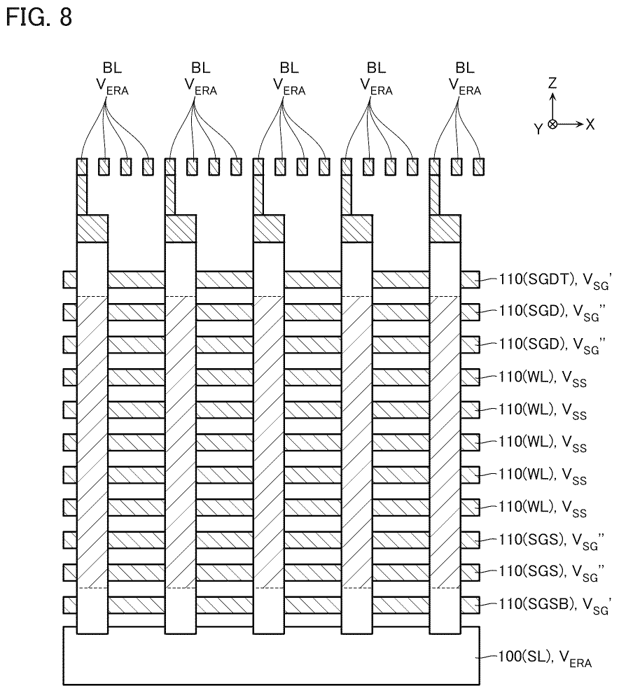

FIG. 8 is a schematic cross-sectional view for describing the erase operation.

In the erase operation, an erase voltage V_{ERA} is applied to the bit lines BL and the source line SL. For example, the erase voltage V_{ERA} may be greater than the program voltage V_{PGM}, and may be equal to the program voltage V_{PGM}.

In the erase operation, a voltage V_{SG}′ is applied to the drain-side select gate line SGDT. The voltage V_{SG}′ is smaller than the erase voltage V_{ERA}. Thus, a Gate Induced Drain Leakage (GIDL) occurs in the drain-side select transistor STDT, and electron and hole pair occurs. The electrons move to the bit line BL side, and the holes move to a memory cell MC side.

In the erase operation, a voltage V_{SG}″ is applied to the drain-side select gate line SGD. The voltage V_{SG}″ is smaller than the erase voltage V_{ERA} and greater than the voltage V_{SG}′. Therefore, a hole channel is formed in the channel region of the drain-side select transistor STD, and the holes are transferred to the memory cell MC side.

In the erase operation, the voltage V_{SG}′ is applied to the source-side select gate line SGSB. Thus, the GIDL occurs in the source-side select transistor STSB, and electron and hole pair occurs. The electrons move to the source line SL side, and the holes move to the memory cell MC side.

In the erase operation, the voltage V_{SG}″ is applied to the source-side select gate line SGS. Therefore, a hole channel is formed in the channel region of the source-side select transistor STS, and the holes are transferred to the memory cell MC side.

In the erase operation, the ground voltage V_{SS} is applied to the word lines WL. Accordingly, the holes in the channel of the semiconductor column 120 tunnel into the electric charge accumulating film in the gate insulating film 130 (FIG. 5). Accordingly, the threshold voltage of the memory cell MC decreases.

### Configuration of Peripheral Circuit PC

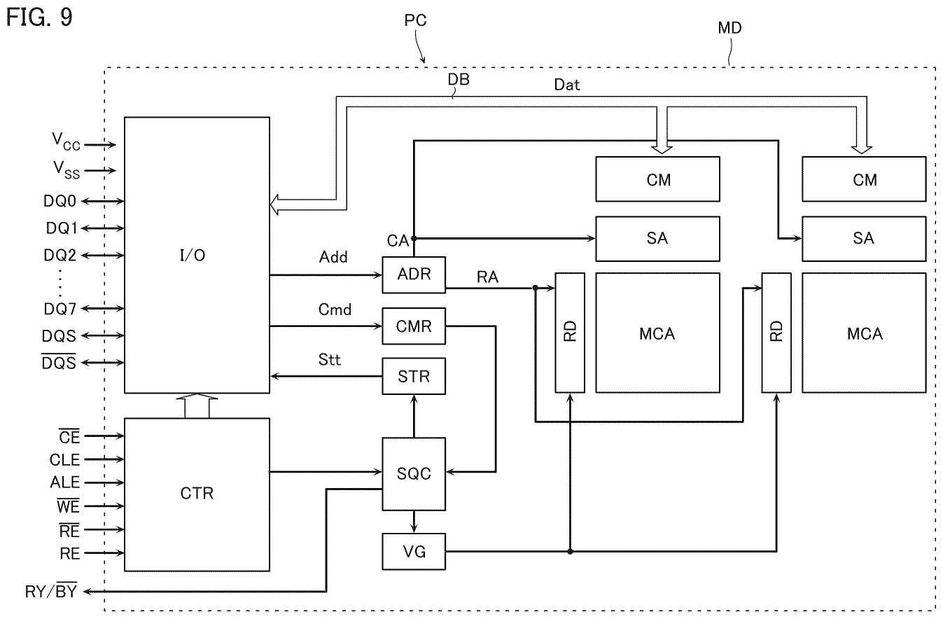

FIG. 9 is a schematic block diagram illustrating a configuration of the peripheral circuit PC.

FIG. 9 illustrates a plurality of control terminals and the like. These plurality of control terminals are represented as control terminals corresponding to a high active signal (a positive logic signal) in some cases, represented as control terminals corresponding to a low active signal (a negative logic signal) in some cases, and represented as control terminals corresponding to both the high active signal and the low active signal in some cases. In FIG. 9, a reference sign of the control terminal corresponding to the low active signal includes an overline (overbar). In this specification, a reference sign of the control terminal corresponding to the low active signal includes a slash (“/”). The description of FIG. 9 is an example, and specific aspects are appropriately adjustable. For example, a part of or all of the high active signals can be changed to the low active signals, or a part of or all of the low active signals can be changed to the high active signals.

Next to the plurality of control terminals illustrated in FIG. 9, arrows indicating input/output directions are illustrated. In FIG. 9, the control terminals with left-right arrows can be used for inputting data or other signals from the controller die CD to the memory die MD. In FIG. 9, the control terminals with right-left arrows can be used for outputting data or other signals from the memory die MD to the controller die CD. In FIG. 9, the control terminals with left-right double arrows can be used for both of inputting data or other signals from the controller die CD to the memory die MD and outputting data or other signals from the memory die MD to the controller die CD.

The peripheral circuit PC includes a row decoder RD and a sense amplifier SA connected to the memory cell array MCA, and a cache memory CM connected to the sense amplifier. The peripheral circuit PC includes a voltage generation circuit VG and a sequencer SQC. The peripheral circuit PC includes an input/output control circuit I/O, a logic circuit CTR, an address register ADR, a command register CMR, and a status register STR.

The row decoder RD includes, for example, a block decoder that decodes a block address in a row address RA included in address data Add, and a voltage transfer circuit that electrically conducts the plurality of word lines WL (FIG. 4) included in one of the plurality of memory blocks BLK and a plurality of voltage supply lines (not illustrated) according to an output signal from the block decoder.

The sense amplifier SA includes a plurality of sense circuits and a plurality of voltage transfer circuits connected to the plurality of bit lines BL, and a data latch circuit. For example, the sense circuit latches data “0” or “1” based on the voltage or current of the bit line BL in the data latch circuit according to the control signal from the sequencer SQC. For example, the voltage transfer circuit adjusts the voltage of the bit line BL to “H” or “L” based on the data “0” or “1” latched in the data latch circuit according to the control signal from the sequencer SQC. User data Dat in the data latch circuit is output to the input/output control circuit I/O via the cache memory CM and the data bus DB. The user data Dat output from the input/output control circuit I/O is latched in the data latch circuit of the sense amplifier SA via the data bus DB and the cache memory CM.

The voltage generation circuit VG includes, for example, a step-up circuit, such as a charge pump circuit, and a step-down circuit, such as a regulator. These step-up circuit and step-down circuit are each connected to a voltage supply line to which a power supply voltage V_{CC} and the ground voltage V_{SS} are applied. These voltage supply lines are connected to, for example, the pad electrodes P described with reference to FIG. 2 and FIG. 3. For example, the voltage generation circuit VG generates a plurality of operating voltages applied to the bit line BL, the source line SL, the word line WL, and the select gate lines SGD, SGS in the read operation, the write operation, and the erase operation on the memory cell array MCA, in accordance with a control signal from the sequencer SQC, and the voltage generation circuit VG applies the operating voltages to the bit line BL, the source line SL, the word line WL, and the select gate lines SGDT, SGD, SGS, and SGSB via a plurality of voltage supply lines. The operating voltage output from the voltage supply line is appropriately adjusted in accordance with the control signal from the sequencer SQC.

The sequencer SQC outputs an internal control signal to the row decoder RD, the sense amplifier module SAM, and the voltage generation circuit VG in response to command data Cmd input to the command register CMR. The sequencer SQC outputs status data Stt indicating the state of the memory die MD to the status register STR as appropriately.

The sequencer SQC generates a ready/busy signal and outputs the ready/busy signal to a terminal RY//BY. The terminal RY//BY enters an “L” state during execution of operations of applying a voltage to the memory cell array MCA, such as the read operation, the write operation, and the erase operation, and otherwise enters an “H” state. In a period where the terminal RY//BY is in the “L” state (a busy period), an access to the memory die MD is basically inhibited. In a period where the terminal RY//BY is in the “H” state (a ready period), the access to the memory die MD is permitted. The terminal RY//BY is achieved by, for example, the pad electrode P described with reference to FIG. 2 and FIG. 3.

The address register ADR is connected to the input/output control circuit I/O and stores the address data Add input from the input/output control circuit I/O. The address register ADR includes, for example, a plurality of 8-bit register arrays. For example, when an internal operation, such as the read operation, the write operation, or the erase operation, is executed, the register array latches the address data Add corresponding to the internal operation being executed.

The address data Add includes, for example, the column address CA and the row address RA. The row address RA includes, for example, a block address identifying the memory block BLK (FIG. 4), a page address identifying the string unit SU and the word line WL, a plane address identifying the memory cell array MCA, and a chip address identifying the memory die MD.

The command register CMR is connected to the input/output control circuit I/O and receives the command data Cmd from the input/output control circuit I/O. When the command data Cmd is input to the command register CMR, a control signal is transmitted to the sequencer SQC.

The status register STR is connected to the input/output control circuit I/O and stores the status data Stt output to the input/output control circuit I/O. The status register STR includes, for example, a plurality of 8-bit register arrays. For example, when an internal operation, such as the read operation, the write operation, or the erase operation, is executed, the register array latches the status data Stt related to the internal operation being executed. Further, the register array latches, for example, ready/busy information of the memory cell array MCA.

The input/output control circuit I/O includes data signal input/output terminals DQ0 to DQ7, data strobe signal input/output terminals DQS, /DQS, a plurality of input circuits and driver circuits connected to the respective data signal input/output terminals DQ0 to DQ7, and a shift register connected to these plurality of input circuits and driver circuits. The input circuit is, for example, a receiver (Input Receiver), such as a comparator. The driver circuit functions as, for example, an Off Chip Driver (OCD) circuit that outputs data and adjusts an output impedance at the output of data. The driver circuit functions as a circuit that adjusts an input impedance at the input of data. In the following description, this driver circuit is referred to as a termination resistor adjustment circuit.

Each of the data signal input/output terminals DQ0 to DQ7 and the data strobe signal input/output terminals DQS, /DQS is achieved by, for example, the pad electrode P described with reference to FIG. 2 and FIG. 3. Data input via the data signal input/output terminals DQ0 to DQ7 are input to the cache memory CM, the address register ADR, or the command register CMR in response to an internal control signal from the logic circuit CTR. Data output via the data signal input/output terminals DQ0 to DQ7 are output from the cache memory CM or the status register STR in response to the internal control signal from the logic circuit CTR.

Signals (such as, a data strobe signal and its complementary signal) input via the data strobe signal input/output terminals DQS, /DQS are used for the input of the data via the data signal input/output terminals DQ0 to DQ7. The data input via the data signal input/output terminals DQ0 to DQ7 is retrieved in the shift register in the input/output control circuit I/O at a timing of a voltage rise of the data strobe signal input/output terminal DQS and a voltage fall of the data strobe signal input/output terminal /DQS, and at a timing of a voltage fall of the data strobe signal input/output terminal DQS and a voltage rise of the data strobe signal input/output terminal /DQS.

The logic circuit CTR includes a plurality of external control terminals /CE, CLE, ALE, /WE, /RE, and RE and logic circuits connected to these plurality of external control terminals /CE, CLE, ALE, /WE, /RE, and RE. The logic circuit CTR receives an external control signal from the controller die CD via the external control terminals /CE, CLE, ALE, /WE, /RE, and RE and outputs the internal control signal to the input/output control circuit I/O in response to the external control signal. In the following description, the external control terminal /CE may be referred to as a “chip enable signal input terminal /CE”.

The respective external control terminals /CE, CLE, ALE, /WE, /RE, and RE are achieved by, for example, the pad electrodes P described with reference to FIG. 2 and FIG. 3.

A signal (such as, a chip enable signal) input via the external control terminal /CE is used for selection of the memory die MD. The memory die MD in which “L” is input to the external control terminal /CE enters a state where an input/output of the user data Dat, the command data Cmd, and the address data Add (hereinafter, may be simply referred to as “data”) is possible. The memory die MD in which “H” is input to the external control terminal /CE enters a state where the input/output of the data is impossible.

A signal (such as, a command latch enable signal) input via the external control terminal CLE is used when the command register CMR is used. When “H” is input to the external control terminal CLE, the data input via the data signal input/output terminals DQ0 to DQ7 is stored as the command data Cmd in the buffer memory in the input/output control circuit I/O and transferred to the command register CMR.

A signal (such as, an address latch enable signal) input via the external control terminal ALE is used when the address register ADR is used. When “H” is input to the external control terminal ALE, the data input via the data signal input/output terminals DQ0 to DQ7 is stored as the address data Add in the buffer memory in the input/output control circuit I/O and transferred to the address register ADR.

When “L” is input to both the external control terminals CLE and ALE, the data input via the data signal input/output terminals DQ0 to DQ7 is stored as the user data Dat in the shift register in the input/output control circuit I/O. The user data Dat stored in the shift register is transferred to the cache memory CM via the bus DB.

A signal (such as, a write enable signal) input via the external control terminal /WE is used for the input of the data via the data signal input/output terminals DQ0 to DQ7. The data input via the data signal input/output terminals DQ0 to DQ7 is retrieved in the shift register, the command register CMR, or the address register ADR in the input/output control circuit I/O at a timing of voltage rise (switching of the input signal) of the external control terminal /WE.

For the input of the data, the external control terminal /WE may be used, or the data strobe signal input/output terminals DQS, /DQS may be used.

Signals (such as, a read enable signal and its complementary signal) input via the external control terminals /RE, RE are used for the output of the data via the data signal input/output terminals DQ0 to DQ7. The data input via the data signal input/output terminals DQ0 to DQ7 is switched at a timing of voltage rise of the external control terminal RE and voltage fall of the external control terminal /RE, and a timing of voltage fall of the external control terminal RE and voltage rise of the external control terminal /RE.

### Configuration of Termination Resistor Adjustment Circuit in Input/Output Control Circuit I/O

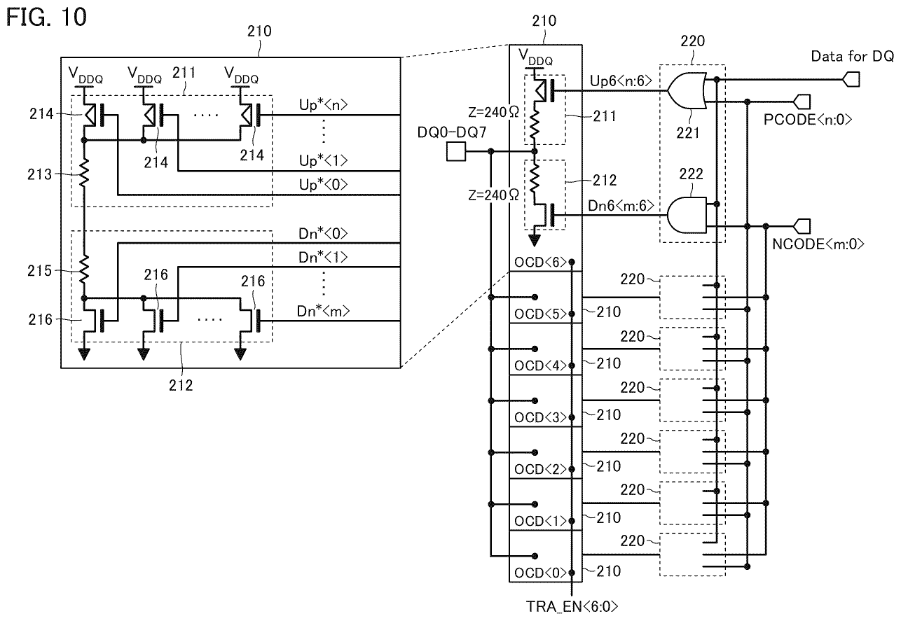

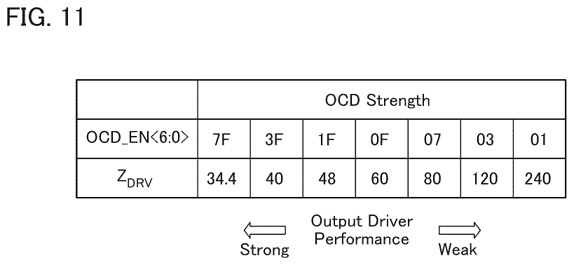

FIG. 10 is a schematic circuit diagram illustrating a configuration of the termination resistor adjustment circuit in the input/output control circuit I/O. FIG. 11 is a table for describing the termination resistor adjustment circuit.

The termination resistor adjustment circuit includes seven termination resistor adjustment units 210 connected in parallel to the data signal input/output terminals DQ0 to DQ7 and the data strobe signal input/output terminals DQS, /DQS, and seven termination resistor adjustment unit control circuits 220 connected to these seven termination resistor adjustment units 210.

The seven termination resistor adjustment units 210 each have an impedance of 240Ω. The seven termination resistor adjustment units 210 are connected to respective signal lines TRA_EN <6:0>, and the number of the termination resistor adjustment units 210 to be driven is controlled based on the signal lines TRA_EN <6:0>. For example, when a signal 0000001 (01 in hexadecimal) is input to the signal lines TRA_EN <6:0>, as illustrated in FIG. 11, an impedance Z_{DRV} of the termination resistor adjustment circuit is set to about 240Ω. For example, a signal 0011111 (1F in hexadecimal) is input to the signal lines TRA_EN <6:0>, the impedance Z_{DRV} of the termination resistor adjustment circuit is set to about 240Ω/5=48Ω. The signal of the signal lines TRA_EN <6:0>is controlled by, for example, a user.

For example, as illustrated in FIG. 10, each of the termination resistor adjustment units 210 includes a pull-up circuit 211 connected between a voltage supply line to which a voltage V_{DDQ} is applied and the data signal input/output terminals DQ0 to DQ7 and the data strobe signal input/output terminals DQS, /DQS. Each of the termination resistor adjustment units 210 includes a pull-down circuit 212 connected between the data signal input/output terminals DQ0 to DQ7 and the data strobe signal input/output terminal DQS, /DQS and the pad electrode P to which the ground voltage V_{SS} is applied.

The pull-up circuit 211 includes a resistor element 213 connected to the data signal input/output terminals DQ0 to DQ7 or the data strobe signal input/output terminals DQS, /DQS, and n+1 (n is a natural number) transistors 214 connected in parallel between the resistor element 213 and the voltage supply line to which the voltage V_{DDQ} is applied. The transistor 214 is a PMOS transistor. The n+1 transistors 214 have at least one of mutually different channel widths and mutually different channel lengths, and have n+1 different resistance values. The n+1 transistors 214 have gate electrodes connected to respective signal lines Up* <0> to Up* <n> (* is any of 0 to 6). n+1 bits of data input to the signal lines Up* <0> to Up* <n> are adjusted such that the impedance at the driving of the pull-up circuit 211 becomes about 240Ω.

The pull-down circuit 212 includes a resistor element 215 connected to the data signal input/output terminals DQ0 to DQ7 or the data strobe signal input/output terminals DQS, /DQS, and m+1 (m is a natural number) transistors 216 connected in parallel between the resistor element 215 and a pad electrode P to which the ground voltage V_{SS} is applied. The transistor 216 is an NMOS transistor. The m+1 transistors 216 have at least one of mutually different channel widths and mutually different channel lengths, and have m+1 different resistance values. The m+1 transistors 216 have gate electrodes connected to respective signal lines Dn* <0> to Dn* <m> (* is any of 0 to 6). In the following configuration, m+1 bits of data input to the signal lines Dn* <0> to Dn* <m> is adjusted such that the impedance at the driving of the pull-down circuit 212 becomes about 240Ω.

The termination resistor adjustment unit control circuit 220 includes, for example, n+1 OR circuits 221 and m+1 AND circuits 222.

At the output of data, signals of “1” or “0” output from the data signal input/output terminals DQ0 to DQ7 or clock signals output from the data strobe signal input/output terminals DQS, /DQS are input to one input terminals of the n+1 OR circuits 221. Further, corresponding bits of n+1 bits of data PCODE <n:0> corresponding to the n+1 PMOS transistors included in the pull-up circuit 211 are input to the other input terminals of the n+1 OR circuits 221.

At the output of data, signals of “1” or “0” output from the data signal input/output terminals DQ0 to DQ7 or clock signals output from the data strobe signal input/output terminals DQS, /DQS are input to one input terminals of the m+1 AND circuits 222. Further, corresponding bits of m+1 bits of data NCODE <m:0> corresponding to the m+1 NMOS transistors included in the pull-down circuit 212 are input to the other input terminals of the m+1 AND circuits 222.

At the input of data, signals of the one input terminals of the n+1 OR circuits 221 and the one input terminals of the m+1 AND circuits 222 are fixed to “1” or “0”. Further, corresponding bits of the n+1 bits of data PCODE <n:0> and corresponding bits of the m+1 data NCODE <m:0> are input to the other input terminals of the n+1 OR circuits 221 and the other input terminals of the m+1 AND circuits 222, respectively.

The data PCODE <n:0> used at the input of data may be different from the data PCODE <n:0> used at the output of data. Similarly, the data NCODE <m:0> used at the input of data may be different from the data NCODE <m:0> used at the output of data.

### Configuration of ZQ Circuit

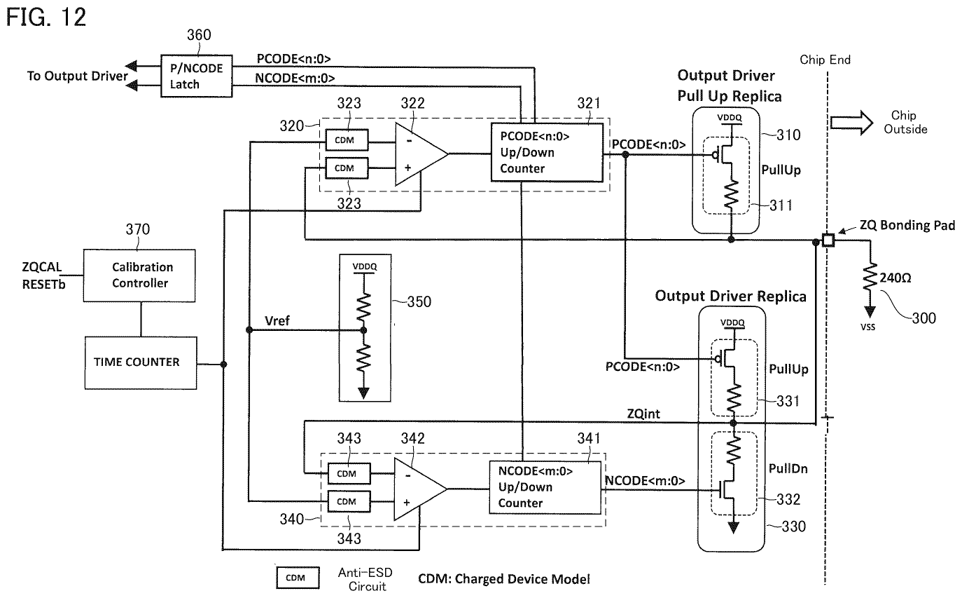

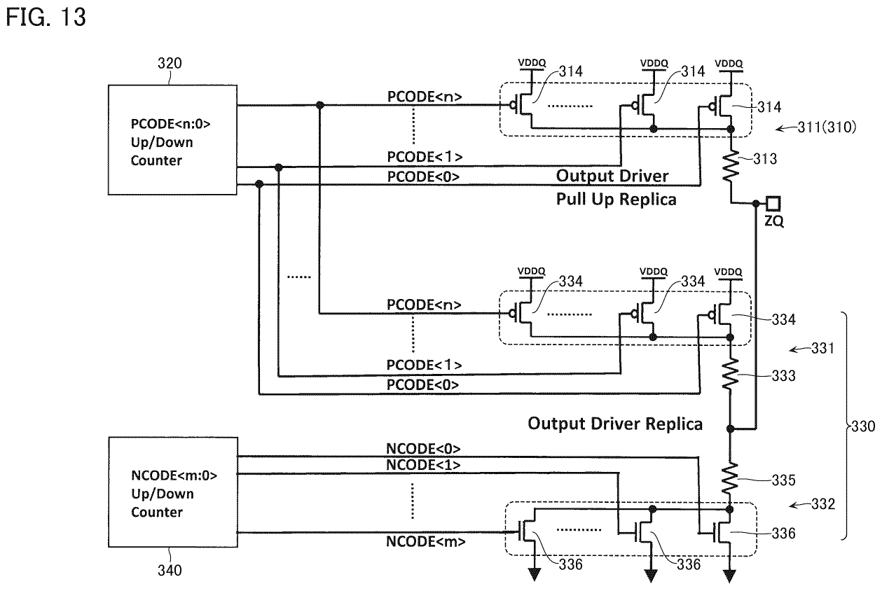

FIG. 12 and FIG. 13 are schematic circuit diagrams illustrating a configuration of a ZQ circuit.

Although the description is omitted in FIG. 9, the peripheral circuit PC includes a ZQ circuit. The ZQ circuit adjusts the data PCODE <n:0> and the data NCODE <m:0> such that the impedances at the driving of the pull-up circuit 211 and the pull-down circuit 212 become about 240Ω.

As illustrated in FIG. 12, the ZQ circuit includes a first replica unit 310 connected to a calibration electrode ZQ, a first replica unit control circuit 320 connected to the first replica unit 310, a second replica unit 330 connected to the calibration electrode ZQ, a second replica unit control circuit 340 connected to the second replica unit 330, a reference voltage generation circuit 350, a data latch circuit 360, and a calibration control circuit 370.

The first replica unit 310 includes a pull-up circuit 311 connected between the voltage supply line to which the voltage V_{DDQ} is applied and the calibration electrode ZQ.

As illustrated in FIG. 13, the pull-up circuit 311 includes a resistor element 313 connected to the calibration electrode ZQ, and n+1 transistors 314 connected in parallel between the resistor element 313 and the voltage supply line to which the voltage V_{DDQ} is applied. The transistor 314 is a PMOS transistor. The n+1 transistors 314 have at least one of mutually different channel widths and mutually different channel lengths, and have n+1 different resistance values. The n+1 transistors 314 have gate electrodes connected to respective n+1 signal lines. The data PCODE <n:0> is input to these n+1 signal lines.

As illustrated in FIG. 12, the first replica unit control circuit 320 includes a counter 321 that outputs the data PCODE <n:0>, a comparator 322 that controls the counter 321, and an anti-ESD circuit 323 connected to an input terminal of the comparator 322.

The counter 321 adjusts the data PCODE <n:0> in synchronization with the clock signal. For example, when the output signal of the comparator 322 is in the “L” state, 1 is subtracted from a value that the n+1 bits of data PCODE <n:0> indicates. When the output signal of the comparator 322 is in the “H” state, the counter 321 adds 1 to the value that the n+1 bits of data PCODE <n:0> indicates.

The comparator 322 has an inverting input terminal connected to the reference voltage generation circuit 350 via the anti-ESD circuit 323. The comparator 322 has a non-inverting input terminal connected to the calibration electrode ZQ via the anti-ESD circuit 323. The comparator 322 is controlled by the calibration control circuit 370.

The anti-ESD circuit 323 protects the comparator 322 from rapid charging and discharging due to static electricity and the like.

The second replica unit 330 includes a pull-up circuit 331 connected between the voltage supply line to which the voltage V_{DDQ} is applied and the calibration electrode ZQ. The second replica unit 330 includes a pull-down circuit 332 connected between the calibration electrode ZQ and an electrode to which the ground voltage V_{SS} is applied.

As illustrated in FIG. 13, the pull-up circuit 331 includes a resistor element 333 connected to the calibration electrode ZQ, and n+1 transistors 334 connected in parallel between the resistor element 333 and the voltage supply line to which the voltage V_{DDQ} is applied. The transistor 334 is a PMOS transistor. The n+1 transistors 334 have at least one of mutually different channel widths and mutually different channel lengths, and have n+1 different resistance values. The n+1 transistors 334 have gate electrodes connected to respective n+1 signal lines. The data PCODE <n:0> is input to these n+1 signal lines.

As illustrated in FIG. 13, the pull-down circuit 332 includes a resistor element 335 connected to the calibration electrode ZQ, and m+1 transistors 336 connected in parallel between the resistor element 335 and an electrode to which the ground voltage V_{SS} is applied. The transistor 336 is an NMOS transistor. The m+1 transistors 336 have at least one of mutually different channel widths and mutually different channel lengths, and have m+1 different resistance values. The m+1 transistors 336 have gate electrodes connected to respective m+1 signal lines. The data NCODE <m:0> is input to these m+1 signal lines.

As illustrated in FIG. 12, the second replica unit control circuit 340 includes a counter 341 that outputs the data NCODE <m:0>, a comparator 342 that controls the counter 341, and an anti-ESD circuit 343 connected to an input terminal of the comparator 342.

The counter 341 adjusts the data NCODE <m:0> in synchronization with the clock signal. For example, when the output signal of the comparator 342 is in the “L” state, 1 is added to a value that the m+1 bits of data NCODE <m:0> indicates. When the output signal of the comparator 342 is in the “H” state, the counter 341 subtracts 1 from the value that the m+1 bits of data NCODE <m:0> indicates.

The comparator 342 has an inverting input terminal connected to the reference voltage generation circuit 350 via the anti-ESD circuit 343. The comparator 342 has a non-inverting input terminal connected to the calibration electrode ZQ via the anti-ESD circuit 343. The comparator 342 is controlled by the calibration control circuit 370.

The anti-ESD circuit 343 protects the comparator 342 from rapid charging and discharging due to static electricity and the like.

The reference voltage generation circuit 350 includes, for example, a voltage dividing circuit. The voltage dividing circuit includes two resistor elements connected in series between the voltage supply line to which the voltage V_{DDQ} is applied and the electrode to which the ground voltage V_{SS} is applied, and an output terminal connected between these two resistor elements. The two resistor elements have the same resistance value, and the voltage of the output terminal is a voltage that is a half of the voltage of the voltage supply line to which the voltage V_{DDQ} is applied.

The data latch circuit 360 latches the data PCODE <n:0> output from the first replica unit control circuit 320 and the data NCODE <m:0> output from the second replica unit control circuit 340, and outputs the data PCODE <n:0> and the data NCODE <m:0> to the termination resistor adjustment circuit.

The calibration control circuit 370 controls the first replica unit control circuit 320 and the second replica unit control circuit 340. For example, the calibration control circuit 370 controls the first replica unit control circuit 320 to adjust the data PCODE <n:0>, and subsequently, controls the second replica unit control circuit 340 to adjust the data NCODE <m:0>.

### Operation of ZQ Circuit

In a calibration operation of the semiconductor device according to the embodiment, the first replica unit control circuit 320 is controlled to adjust the data PCODE <n:0>. Here, the calibration electrode ZQ is connected to the voltage supply line to which the voltage V_{DDQ} is applied via the pull-up circuit 311, and connected to an electrode to which the ground voltage V_{SS} is applied outside the semiconductor device via a series resistor 300 having a resistance value of about 240Ω. By controlling the first replica unit control circuit 320, the data PCODE <n:0> is adjusted such that the voltage of a calibration electrode ZQm of the memory die MD0 becomes approximately the reference voltage (½V_{DDQ}). Accordingly, the data PCODE <n:0> is adjusted such that the impedance at the driving of the pull-up circuit 311 becomes about 240Ω. Then, the data latch circuit 360 latches the data PCODE <n:0> output from the first replica unit control circuit 320.

Next, the second replica unit control circuit 340 is controlled to adjust the data NCODE <m:0>. Here, the calibration electrode ZQ is connected to the voltage supply line to which the voltage V_{DDQ} is applied via the pull-up circuit 331, and connected to the electrode to which the ground voltage V_{SS} is applied via the pull-down circuit 332. The impedance of the pull-up circuit 331 is adjusted to approximately 240Ω. By controlling the second replica unit control circuit 340, the data NCODE <m:0> is adjusted such that the voltage of the calibration electrode ZQ becomes approximately the reference voltage (½V_{DDQ}). Accordingly, the data NCODE <m:0> is adjusted such that the impedance at the driving of the pull-down circuit 332 becomes about 240Ω. Then, the data latch circuit 360 latches the data NCODE <m:0> output from the second replica unit control circuit 340.

### Two Patterns of Acquiring Data PCODE <n:0>, NCODE <m:0>

The ZQ circuit may include two sets of the first replica unit 310 and the first replica unit control circuit 320 to adjust both the data PCODE <n:0> used for the data output and the data PCODE <n:0> used for the data input. Similarly, the ZQ circuit may include two sets of the second replica unit 330 and the second replica unit control circuit 340 to adjust both the data NCODE <m:0> used for the data output and the data NCODE <m:0> used for the data input.

For example, the data PCODE <n:0> and NCODE <m:0> used for the data input may be same as the data PCODE <n:0> and NCODE <m:0> used for the data output, and may be calculated based on the data PCODE <n:0> and NCODE <m:0> used for the data output.

### Period in Which Calibration Operation is Executable

The impedances of the pull-up circuit 211 and the pull-down circuit 212 in the termination resistor adjustment circuit vary in accordance with changes of power supply voltage, temperature, and the like. Therefore, the calibration operation is preferred to be appropriately executed in accordance with the change of operating conditions.

Here, the semiconductor device according to the embodiment is configured to be able to perform the calibration operation concurrently with the core operation. With this configuration, a semiconductor device that appropriately operates without taking a time for the calibration operation can be provided.

However, there is a time period unsuitable for executing the calibration operation during the execution of the core operation. For example, in a time period immediately after inputting a command that instructs the execution of the core operation and the like to the memory die MD, the voltage used for the operation (for example, in the case of the read operation, the read voltage V_{CGR}, the read pass voltage V_{READ}, and the like) is generated in the voltage generation circuit VG. At the execution of the read operation and the like, the current flows from the bit line BL to the source line SL. In these time periods, the power supply voltage, the temperature, and the like change in some cases.

Therefore, in the semiconductor device according to the embodiment, the time period during the core operation is divided into a time period in which the execution of the calibration operation is permitted and a time period in which the execution of the calibration operation is not permitted. With this configuration, the impedances at the driving of the pull-up circuit 211 and the pull-down circuit 212 can be adjusted to the appropriate values with more certainty through the calibration operation.

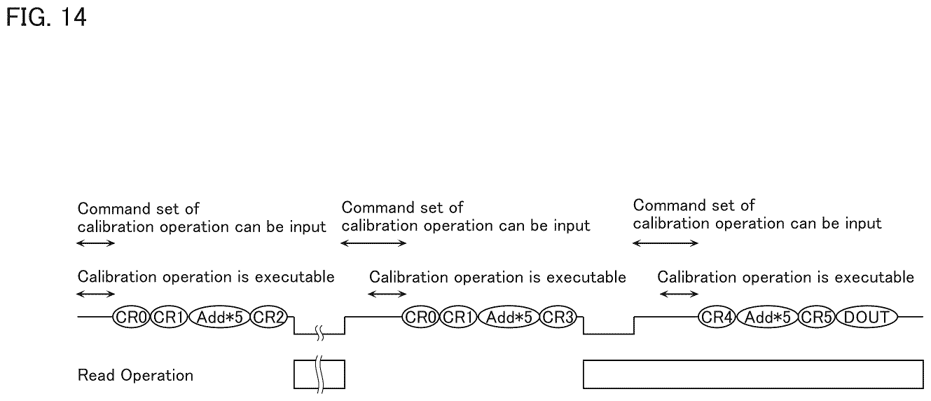

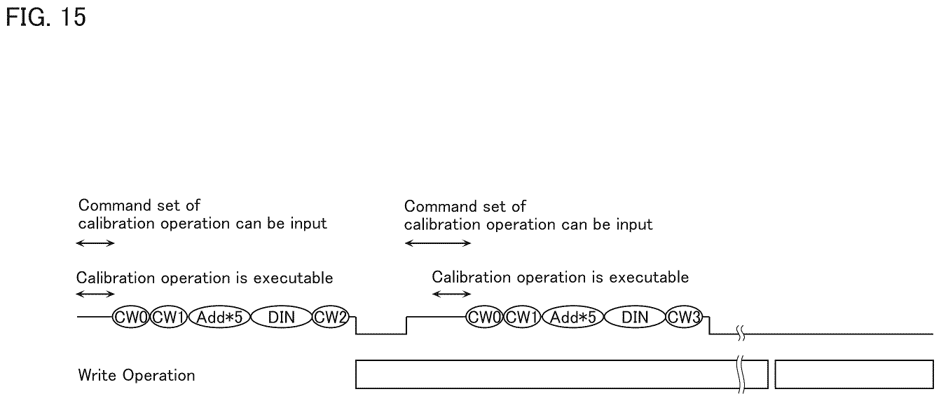

The time period in which the calibration operation is executable is described below. FIG. 14 and FIG. 15 are timing charts for describing the time period in which the calibration operation is executable.

FIG. 14 illustrates command sets input to the memory die MD at the read operation and the like. The first command set corresponds to a normal read operation. The second command set corresponds to a cache read operation. The third command set corresponds to a data-out operation.

The normal read operation and the cache read operation are approximately similarly executed. However, when the normal read operation is executed, the memory die MD becomes a busy state until a timing of completing the read operation. Meanwhile, when the cache read operation is executed, the memory die MD becomes a cache ready state before completing the read operation. The data-out operation is an operation of outputting the user data read from the memory cell array MCA and output to the cache memory CM through the read operation to the controller die CD via the data signal input/output terminals DQ0 to DQ7.

In the illustrated example, at a timing of inputting the first command set, the memory die MD is in a ready state and the terminal RY//BY is in the “H” state.

The first command set includes data CR0, CR1, Add, and CR2.

That is, the controller die CD (FIG. 1) inputs the data CR0 and CR1 as the command data Cmd to the memory die MD. That is, in a state where the voltages of the data signal input/output terminals DQ0 to DQ7 are set to “H” or “L” corresponding to the respective bits of the data CR0 and CR1, “H” is input to the external control terminal CLE, and “L” is input to the external control terminal ALE, the external control terminal /WE is raised from “L” to “H”. The data CR0 and CR1 is a command input at the start of the read operation.

Next, the controller die CD inputs the address data Add to the memory die MD. That is, in a state where the voltages of the data signal input/output terminals DQ0 to DQ7 are set to “H” or “L” corresponding to the respective bits of the address data Add, “L” is input to the external control terminal CLE, and “H” is input to the external control terminal ALE, the external control terminal /WE is raised from “L” to “H”. The address data Add is input five times.

Next, the controller die CD inputs the data CR2 as the command data Cmd to the memory die MD. The data CR2 is a command that indicates completion of the input of the command set relating to the normal read operation.

When the first command set is input, the memory die MD becomes the busy state, and the terminal RY//BY becomes from the “H” state to the “L” state. Accordingly, the access to the memory die MD is inhibited. Further, the read operation starts in the memory die MD.

When the read operation is completed, the memory die MD becomes the ready state, and the terminal RY//BY becomes from the “L” state to the “H” state. Accordingly, the access to the memory die MD is permitted. In the illustrated example, the second command set is input in this state.

The second command set is basically similar to the first command set. However, in the second command set, data CR3 is input instead of the data CR2. The data CR3 is a command that indicates completion of the input of the command set relating to the cache read operation.

When the second command set is input, the memory die MD becomes the busy state, and the terminal RY//BY becomes from the “H” state to the “L” state. Accordingly, the access to the memory die MD is inhibited. Further, the read operation starts in the memory die MD.

After the elapse of a certain period from the input of the second command set, the memory die MD becomes the cache ready state, and the terminal RY//BY becomes from the “L” state to the “H” state. Accordingly, the access to the memory die MD is permitted. In the illustrated example, the third command set is input in this state.

The third command set includes data CR4, Add, and CR5. The data CR4 is a command input at the start of the data-out operation. The data CR5 is a command that indicates completion of the input of the command set relating to the data-out operation.

When the third command set is input, the controller die CD causes the memory die MD to output the user data via the data signal input/output terminals DQ0 to DQ7. That is, the voltages of the data signal input/output terminals DQ0 to DQ7 are set to “H” or “L” according to the respective bits corresponding to the user data by the termination resistor adjustment units 210 described with reference to FIG. 10. The data output from the data signal input/output terminals DQ0 to DQ7 is switched by switching the signals of the external control terminals /RE, RE. Accordingly, the controller die acquires the data output from the data signal input/output terminals DQ0 to DQ7 while sequentially switching the data output from the external control terminals /RE, RE.

Here, the semiconductor device according to the embodiment is configured to be able to receive the command set that instructs the execution of the calibration operation in the ready state and the cache ready state. In the example of FIG. 14, the state before the input of the first command set and the state after the completion of the normal read operation and before the input of the second command set correspond to the ready state. Further, the state before the input of the third command set from when the terminal RY//BY rises after the input of the second command set corresponds to the cache ready state.

The semiconductor device according to the embodiment is configured to be able to perform the calibration operation in the entire time period in the ready state and a part of the time period in the cache ready state. In the example of FIG. 14, the execution of the calibration operation is permitted in a time period until the memory die MD becomes the busy state after the elapse of the certain period from when the memory die MD becomes the cache ready state.

In the ready state, the core operation is not executed, and in the cache ready state illustrated in FIG. 14, the read operation is executed. Therefore, when the calibration operation is started in this cache ready state, the calibration operation is executed concurrently with the read operation.

FIG. 15 illustrates command sets input to the memory die MD at the write operation and the like. The first command set corresponds to a cache write operation. The second command set corresponds to a normal write operation.

The normal write operation and the cache write operation are approximately similarly executed. However, when the normal write operation is executed, the memory die MD becomes the busy state until a timing of completing the write operation. Meanwhile, when the cache write operation is executed, the memory die MD becomes the cache ready state before completing the write operation.

In the illustrated example, at a timing of inputting the first command set, the memory die MD is in the ready state and the terminal RY//BY is in the “H” state.

The first command set includes data CW0, CW1, Add, DIN, and CW2.

That is, the controller die CD (FIG. 1) inputs the data CW0 and CW1 as the command data Cmd to the memory die MD. The data CW0 and CW1 is a command input at the start of the write operation.

Next, the controller die CD inputs the address data Add to the memory die MD.

Next, the controller die CD inputs the data DIN as the user data Dat to the memory die MD. That is, in a state where the voltages of the data signal input/output terminals DQ0 to DQ7 are set to “H” or “L” corresponding to the respective bits of the data DIN, “L” is input to the external control terminal CLE, and “L” is input to the external control terminal ALE, the input signals of the data strobe signal input/output terminals DQS, /DQS are switched. At this time, the input impedances of the data signal input/output terminals DQ0 to DQ7 are adjusted by the termination resistor adjustment units 210 described with reference to FIG. 10.

Next, the controller die CD inputs the data CW2 as the command data Cmd to the memory die MD. The data CW2 is a command that indicates completion of the input of the command set relating to the cache write operation.

When the first command set is input, the memory die MD becomes the busy state, and the terminal RY//BY becomes from the “H” state to the “L” state. Accordingly, the access to the memory die MD is inhibited. Further, the write operation starts in the memory die MD.

After the elapse of a certain period from the input of the first command set, the memory die MD becomes the cache ready state, and the terminal RY//BY becomes from the “L” state to the “H” state. Accordingly, the access to the memory die MD is permitted. In the illustrated example, the second command set is input in this state.

The second command set is basically similar to the first command set. However, in the second command set, data CW3 is input instead of the data CW2. The data CW3 is a command that indicates completion of the input of the command set relating to the normal write operation.

When the second command set is input, the memory die MD becomes the busy state, and the terminal RY//BY becomes from the “H” state to the “L” state. Accordingly, the access to the memory die MD is inhibited. The write operation corresponding to the second command set is started immediately after the completion of the write operation corresponding to the first command set.

Here, the semiconductor device according to the embodiment is configured to be able to receive the command set that instructs the execution of the calibration operation in the ready state and the cache ready state. In the example of FIG. 15, the state before the input of the first command set corresponds to the ready state. Further, the state before the input of the second command set from when the terminal RY//BY rises after the input of the first command set corresponds to the cache ready state.

The semiconductor device according to the embodiment is configured to be able to perform the calibration operation in the entire time period in the ready state and a part of the time period in the cache ready state. In the example of FIG. 15, similarly to the example of FIG. 14, the execution of the calibration operation is permitted in a time period until the memory die MD becomes the busy state after the elapse of the certain period from when the memory die MD becomes the cache ready state.

In the ready state, the core operation is not executed, and in the cache ready state illustrated in FIG. 15, the write operation is executed. Therefore, when the calibration operation is started in this cache ready state, the calibration operation is executed concurrently with the write operation.

### Configuration of Clock Signal Generation Circuit

In the execution of the calibration operation, a clock signal for the calibration operation is generated and input to the sequencer SQC (FIG. 9).

Here, when the calibration operation is started in a state where the core operation is not executed, the generation of the clock signal is started at a timing of starting the execution of the calibration operation.

On the other hand, when the calibration operation is started in a state where the core operation is executed, for example, it is considered to use the clock signal used for the core operation also for the calibration operation. However, in such a method, a waveform of a clock pulse for the calibration operation is distorted due to a relation between the timing of starting the calibration operation and a phase in the clock signal, thus possibly causing a failure in the calibration operation.

To avoid this, for example, it is also considered to additionally provide a clock signal generation circuit for the calibration operation. However, such a method causes an increase in the circuit area in the entire semiconductor device.

Therefore, the semiconductor device according to the embodiment includes a clock signal generation circuit capable of stably generating a clock pulse for the calibration operation even during the execution of the core operation. The clock signal generation circuit is described below with reference to the drawings.

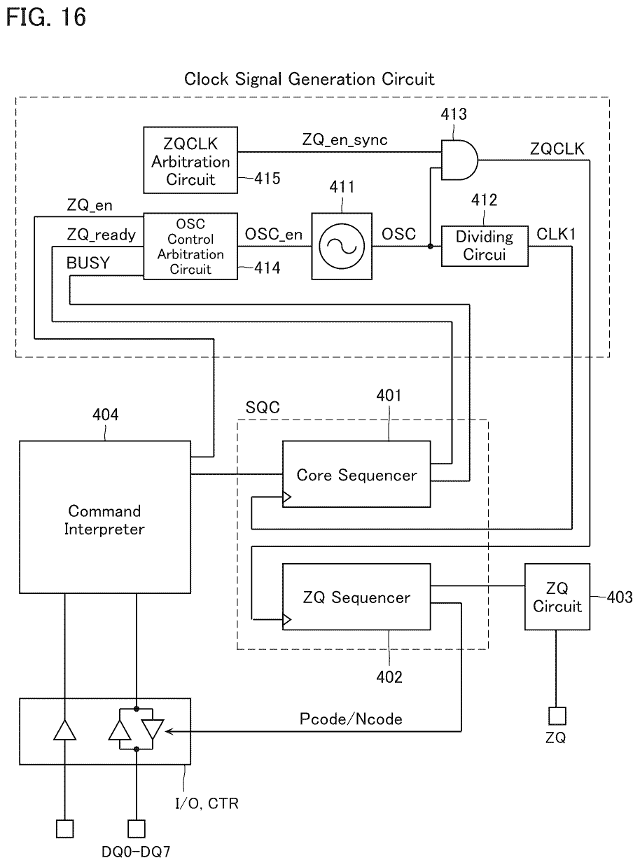

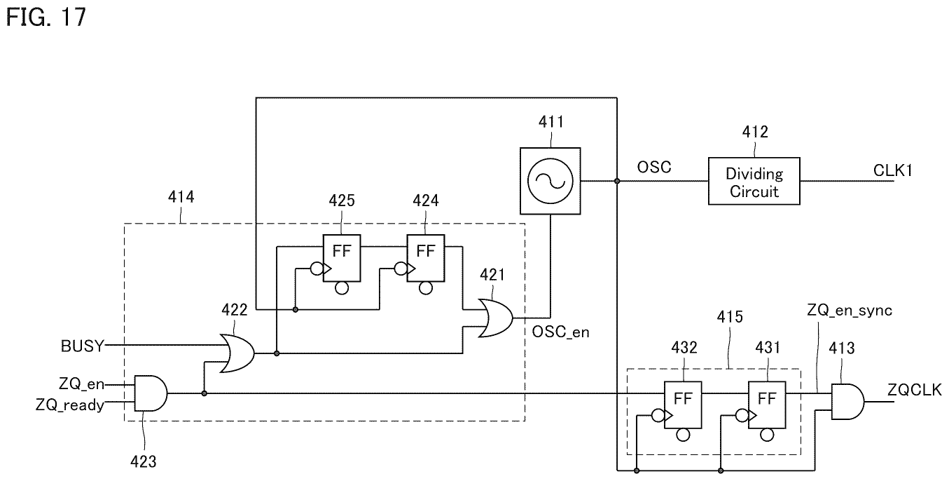

FIG. 16 and FIG. 17 are schematic circuit diagrams for describing the clock signal generation circuit.

As illustrated in FIG. 16, the sequencer SQC described with reference to FIG. 9 includes a core sequencer 401 and a ZQ sequencer 402. The core sequencer 401 controls the internal control signal input to the sense amplifier SA, the voltage generation circuit VG, and the like when the core operation, such as a read operation, a write operation, and an erase operation, is executed. The ZQ sequencer 402 controls the internal control signal input to a ZQ circuit 403 when the calibration operation is executed. This ZQ circuit 403 is the ZQ circuit described with reference to FIG. 12 and FIG. 13.

The clock signal generation circuit outputs a clock signal CLK1 input to the core sequencer 401 and a clock signal ZQCLK input to the ZQ sequencer 402 based on the internal control signal input from the sequencer SQC and a command interpreter 404. The clock signal CLK1 is a clock signal used for the execution of the core operation. The clock signal ZQCLK is a clock signal used for the execution of the calibration operation. The clock signals CLK1 and ZQCLK may have mutually different frequencies.

The clock signal generation circuit includes an oscillator circuit 411 that outputs a clock signal OSC in response to an activation signal OSC_en, a dividing circuit 412 (output circuit) that outputs the clock signal CLK1 in response to the input of the clock signal OSC, and an AND circuit 413 (output circuit) that outputs the clock signal ZQCLK in response to the input of the clock signal OSC and a gate signal ZQ_en_sync.

The clock signal generation circuit includes an OSC control arbitration circuit 414 that inputs the activation signal OSC_en to the oscillator circuit 411, and a ZQCLK arbitration circuit 415 that inputs the gate signal ZQ_en_sync to the AND circuit 413.

The OSC control arbitration circuit 414 includes, as illustrated in FIG. 17, an OR circuit 421 that outputs the activation signal OSC_en.

The OR circuit 421 has one input terminal connected to an output terminal of an OR circuit 422. The OR circuit 422 has one input terminal to which an internal control signal BUSY is input. The internal control signal BUSY becomes the “H” state in response to the input of the command set that instructs the execution of the core operation (for example, the command set described with reference to FIG. 14 and FIG. 15), and becomes the “L” state when the core operation is completed. The OR circuit 422 has the other input terminal connected to an output terminal of an AND circuit 423. The AND circuit 423 has one input terminal to which an internal control signal ZQ_en is input. The internal control signal ZQ_en becomes the “H” state in response to the input of the command set that instructs the execution of the calibration operation, and becomes the “L” state when the calibration operation is completed. The AND circuit 423 has the other input terminal to which an internal control signal ZQ_ready is input. The internal control signal ZQ_ready becomes the “H” state in the time period in which the calibration is executable described with reference to FIG. 14 and FIG. 15, and becomes the “L” state in the other time period.

The OR circuit 421 has the other input terminal connected to an output terminal of a flip-flop circuit 424. The flip-flop circuit 424 has an input terminal connected to an output terminal of a flip-flop circuit 425. The flip-flop circuit 425 has an input terminal connected to the output terminal of the OR circuit 422. The flip-flop circuits 424 and 425 each switch the output signal to the signal input to the input terminal at a timing of fall of the clock signal OSC.

The ZQCLK arbitration circuit 415 includes a flip-flop circuit 431 that outputs the gate signal ZQ_en_sync. The flip-flop circuit 431 has an input terminal connected to an output terminal of a flip-flop circuit 432. The flip-flop circuit 432 has an input terminal to which the output signal of the AND circuit 423 is input. The flip-flop circuits 431 and 432 each switch the output signal to the signal input to the input terminal at a timing of fall of the clock signal OSC.

### Operation of Clock Signal Generation Circuit

When the command set to execute the core operation is input in the case where the memory die MD is in the ready state, the internal control signal BUSY becomes the “H” state. In accordance with this, the output signal of the OR circuit 422 becomes the “H” state, and the output signal (activation signal OSC_en) of the OR circuit 421 also becomes the “H” state. In accordance with this, the output of the clock signal OSC from the oscillator circuit 411 is started, and the output of the clock signal CLK1 from the dividing circuit 412 is also started. When the clock signal OSC falls twice, the output signal of the flip-flop circuit 424 becomes the “H” state.

When the core operation is completed, the internal control signal BUSY becomes the “L” state. In accordance with this, the output signal of the OR circuit 422 becomes the “L” state. However, since the output signal of the flip-flop circuit 424 is kept to be the “H” state, the output signal of the OR circuit 421 is also kept to be the “H” state. When the clock signal OSC falls twice after the internal control signal BUSY is switched to the “L” state, the output signal of the flip-flop circuit 424 becomes the “L” state, and the activation signal OSC_en also becomes the “L” state. In accordance with this, the output of the clock signals OSC, CLK1 is completed.

At a timing of the memory die MD in the ready state, the internal control signal ZQ_ready is in the “H” state. When the command set to execute the calibration operation is input at this timing, the internal control signal ZQ_en becomes the “H” state. In accordance with this, the output signal of the OR circuit 422 becomes the “H” state, and the output signal (activation signal OSC_en) of the OR circuit 421 also becomes the “H” state. Therefore, the clock signal OSC is output from the oscillator circuit 411. When the clock signal OSC falls twice, the output signal (gate signal ZQ_en_sync) of the flip-flop circuit 431 also becomes the “H” state, and the output of the clock signal ZQCLK from the AND circuit 413 is started. The output signal of the flip-flop circuit 424 becomes the “H” state.

When the calibration operation is completed, the internal control signal ZQ_en becomes the “L” state. However, since the output signal of the flip-flop circuit 424 is kept to be the “H” state, the output signal of the OR circuit 421 is also kept to be the “H” state, and the output of the clock signal OSC is also kept. Further, since the output signal of the flip-flop circuit 431 is also kept to be the “H” state, the output signal of the AND circuit 413 is also kept to be the “H” state, and the output of the clock signal ZQCLK is also kept. When the clock signal OSC falls twice after the internal control signal ZQ_en is switched to the “L” state, the output signal of the flip-flop circuit 424 becomes the “L” state, and the activation signal OSC_en also becomes the “L” state. Further, the output signal (gate signal ZQ_en_sync) of the flip-flop circuit 431 also becomes the “L” state. In accordance with this, the output of the clock signal ZQCLK is completed.

When the command set to execute the calibration operation is input at the timing of the memory die MD in the cache ready state, and the internal control signal ZQ_ready is in the “H” state at this timing, the clock signal generation circuit operates approximately similarly to the case where the command set to execute the calibration operation is input at the timing of the memory die MD in the ready state.

When the calibration operation is completed at the timing of the memory die MD in the cache ready state, the clock signal generation circuit operates approximately similarly to the case where the calibration operation is completed at the timing of the memory die MD in the ready state. However, in this case, since the internal control signal BUSY is kept to be the “H” state, the output of the clock signal OSC is not completed. The output of the clock signal ZQCLK is completed when the gate signal ZQ_en_sync becomes the “L” state.

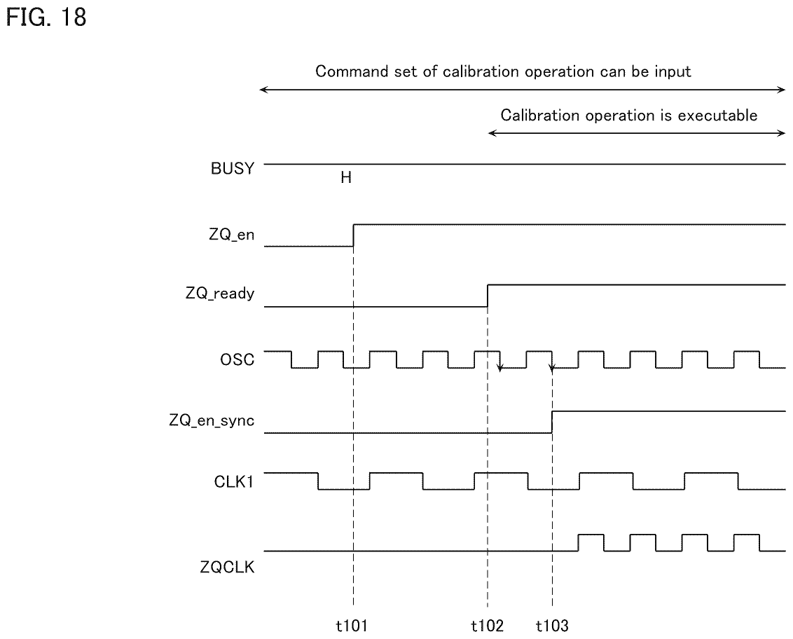

FIG. 18 is a schematic waveform diagram for describing the operation of the clock signal generation circuit.

As illustrated in FIG. 18, at a timing of the memory die MD in the cache ready state, the internal control signal BUSY is in the “H” state, and the output of the clock signal OSC has been already started. Even when the command set to execute the calibration operation is input at such a timing t101, the output signal of the AND circuit 423 is kept to be the “L” state in the case where the internal control signal ZQ_ready is in the “L” state. Therefore, the output of the clock signal ZQCLK is not started. In this case, at timing t103 at which the clock signal OSC falls twice after timing t102 at which the internal control signal ZQ_ready rises to the “H” state, the gate signal ZQ_en_sync becomes the “H” state, and the output of the clock signal ZQCLK from the AND circuit 413 is started.

FIG. 18 illustrates an example in which the frequency of the clock signal CLK1 is a half of the frequency of the clock signal OSC.

### Second Embodiment

Next, a semiconductor device according to the second embodiment is described. In the following description, the same reference numerals are attached to parts similar to those in the first embodiment, and the explanation is omitted.

The semiconductor device according to the second embodiment is basically configured similarly to the semiconductor device according to the first embodiment. However, the semiconductor device according to the second embodiment includes four memory cell arrays MCA0, MCA1, MCA2, and MCA3. These four memory cell arrays MCA can each independently execute the core operation.

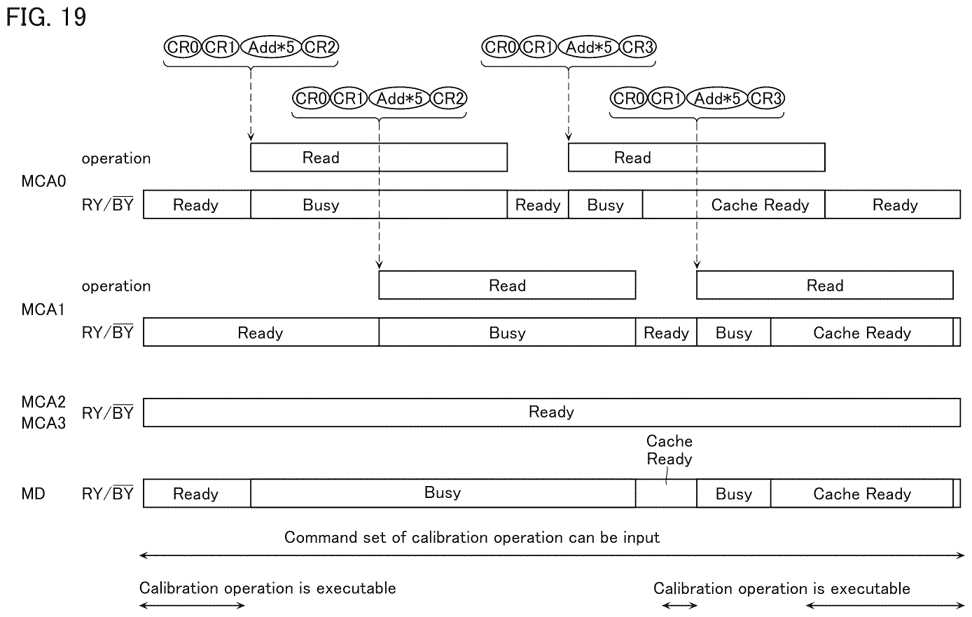

FIG. 19 is a timing chart for describing a timing at which the calibration operation is executable in the semiconductor device according to the second embodiment.

In the illustrated example, first, the command set of the normal read operation corresponding to the memory cell array MCA0 is input, and the memory cell array MCA0 becomes the busy state. In accordance with this, the terminal RY//BY switches from the “H” state to the “L” state.

Next, the command set of the normal read operation corresponding to the memory cell array MCA1 is input, and the memory cell array MCA1 becomes the busy state.

Next, the normal read operation corresponding to the memory cell array MCA0 is completed, and the memory cell array MCA0 becomes the ready state. However, since the normal read operation corresponding to the memory cell array MCA1 is in execution at this timing, the terminal RY//BY is kept to the “L” state.

Next, the command set of the cache read operation corresponding to the memory cell array MCA0 is input, and the memory cell array MCA0 becomes the busy state.

After the elapse of a certain period from the input of the command set of the cache read operation corresponding to the memory cell array MCA0, the memory cell array MCA0 becomes the cache ready state. The normal read operation corresponding to the memory cell array MCA1 is completed, and the memory cell array MCA1 becomes the ready state. In accordance with this, the terminal RY//BY switches from the “L” state to the “H” state.

Next, the command set of the cache read operation corresponding to the memory cell array MCA1 is input, and the memory cell array MCA1 becomes the busy state. In accordance with this, the terminal RY//BY switches from the “H” state to the “L” state.

After the elapse of a certain period from the input of the command set of the cache read operation corresponding to the memory cell array MCA1, the memory cell array MCA1 becomes the cache ready state. In accordance with this, the terminal RY//BY switches from the “L” state to the “H” state.

Here, the semiconductor device according to the embodiment is configured to be able to receive the command set that instructs the execution of the calibration operation when any of the four memory cell arrays MCA is in the ready state or the cache ready state. In the example of FIG. 19, since the memory cell arrays MCA2 and MCA3 are always in the ready state, the command set that instructs the execution of the calibration operation can be input at every timing.

However, in the semiconductor device according to the embodiment, the execution of the calibration operation is permitted only when all of the four memory cell arrays MCA are in the time period in which the execution of the calibration operation is permitted. In the example of FIG. 19, the execution of the calibration operation is permitted in a case where all of the four memory cell arrays MCA0, MCA1, MCA2, and MCA3 become the ready state or the cache ready state and then the certain period is elapsed.

In this embodiment, the controller die CD can confirm whether or not the calibration operation is completed through the status read. In this case, for example, status data corresponding to any memory cell array MCA not in use among the four memory cell arrays MCA is used as data indicating the execution status of the calibration operation.

In this embodiment, the input of the command set that instructs the execution of the calibration operation may be permitted only when the terminal RY//BY is in the “H” state (when the memory die MD is in the ready state or the cache ready state).

### Other Embodiments

The semiconductor devices according to the first embodiment and the second embodiment are described above. However, these configurations are only examples, and the specific configuration and the like can be changed as appropriate. For example, in the first embodiment and the second embodiment, the communication between the memory die MD and the controller die CD may be compliant to a Single data rate (SDR) interface, may be compliant to a toggle Double data rate (DDR) interface, and may be compliant to an Open NAND flash interface (ONFI).

FIG. 17 illustrates flip-flop circuits that switch the output signal to the signal input to the input terminal at the timing of the fall of the clock signal OSC as the example of the flip-flop circuits 424, 425, 431, and 432. However, the flip-flop circuits 424, 425, 431, and 432 may switch the output signal to the signal input to the input terminal at the timing of the rise of the clock signal OSC.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
an electrode;
a pull-up circuit and a pull-down circuit that control a voltage of the electrode in response to input data;
an internal circuit that outputs the data supplied to the pull-up circuit and the pull-down circuit;
a control circuit configured to be able to execute an operation of the internal circuit and a calibration operation to adjust output impedances of the pull-up circuit and the pull-down circuit; and
a clock signal generation circuit that supplies a first clock signal to the control circuit in a state where the calibration operation is in execution, wherein
when an instruction to execute the calibration operation is input during execution of the operation of the internal circuit, the clock signal generation circuit outputs the first clock signal in a first period during execution of the operation and does not output the first clock signal in a second period during execution of the operation in a time period from the input of the instruction to completion of the calibration operation.

2. The semiconductor device according to claim 1, wherein
the clock signal generation circuit includes:
an oscillator circuit that outputs a second clock signal;
a first output circuit that receives the second clock signal and outputs a third clock signal to the control circuit when an instruction to execute the operation of the internal circuit is input; and
a second output circuit that receives the second clock signal and outputs the first clock signal to the control circuit when the instruction to execute the calibration operation is input.

3. The semiconductor device according to claim 2, wherein
the first clock signal and the third clock signal have different frequencies.

4. The semiconductor device according to claim 2, wherein
the first output circuit is a dividing circuit.

5. The semiconductor device according to claim 2, wherein
the clock signal generation circuit receives:
a first internal control signal that becomes a first state in a time period from the input of the instruction to execute the operation of the internal circuit to completion of the operation of the internal circuit, and becomes a second state in the other time period;
a second internal control signal that becomes a third state in a time period from the input of the instruction to execute the calibration operation to the completion of the calibration operation, and becomes a fourth state in the other time period; and
a third internal control signal that becomes a fifth state in the first period and becomes a sixth state in the second period, and
the oscillator circuit outputs the second clock signal:
when the first internal control signal is in the first state; and
when the second internal control signal is in the third state and the third internal control signal is in the fifth state.

6. The semiconductor device according to claim 5, wherein
the clock signal generation circuit further includes a logic circuit configured to output a signal that becomes a seventh state in a case where the first internal control signal is in the first state or in a case where the second internal control signal is in the third state and the third internal control signal is in the fifth state, and becomes an eighth state in the other case, and
the oscillator circuit starts outputting the second clock signal at a timing at which the output signal of the logic circuit switches to the seventh state, and
the oscillator circuit completes the output of the second clock signal at a timing at which the second clock signal rises or falls a predetermined number of times after the output signal of the logic circuit switches to the eighth state.

7. The semiconductor device according to claim 5, wherein
the second output circuit outputs the first clock signal when the second internal control signal is in the third state and the third internal control signal is in the fifth state.

8. The semiconductor device according to claim 6, wherein
the second output circuit starts outputting the second clock signal at the timing at which the second clock signal rises or falls the predetermined number of times after the output signal of the logic circuit switches to the seventh state, and
the second output circuit completes the output of the second clock signal at the timing at which the second clock signal rises or falls the predetermined number of times after the output signal of the logic circuit switches to the eighth state.

9. The semiconductor device according to claim 1, wherein
the internal circuit includes a memory cell that stores the data, and
the operation of the internal circuit is a read operation, a write operation, or an erase operation on the memory cell.

10. The semiconductor device according to claim 1, wherein
the internal circuit further includes a memory string that stores the data, and
the memory string includes a plurality of memory cell transistors connected in series.

11. The semiconductor device according to claim 1, wherein
the semiconductor device is configured to be able to receive the instruction to execute the calibration operation in a ready state and in a cache ready state.

12. The semiconductor device according to claim 1, wherein
the internal circuit includes a plurality of memory cell arrays, and
the semiconductor device is configured to be able to receive the instruction to execute the calibration operation when any of the plurality of memory cell arrays is in a ready state or a cache ready state.

13. The semiconductor device according to claim 12, wherein
the clock signal generation circuit is allowed to output the first clock signal when all of memory cell arrays in execution of the operation among the plurality of memory cell arrays are in the first period, and
the clock signal generation circuit does not output the first clock signal when any of the memory cell arrays in execution of the operation among the plurality of memory cell arrays is in the second period.

14. The semiconductor device according to claim 12, wherein
the semiconductor device is able to output data indicating an execution status of the calibration operation as status data instead of information indicating a state of the memory cell array in the ready state or the cache ready state among the plurality of memory cell arrays.

15. The semiconductor device according to claim 1, wherein
a communication with a controller is compliant to Open Nand Flash Interface (ONFI).
